(19) United States
(12) Patent Application Publication
(10) Pub. No.: US 2013/0057322 A1
(43) Pub. Date: Mar. 7, 2013

(54) DELAY CIRCUIT AND DELAY STAGE THEREOF

(71) Applicant: MING-CHUNG CHOU, HSINCHU CITY (TW)

(72) Inventor: MING-CHUNG CHOU, HSINCHU CITY (TW)

(73) Assignee: ELITE SEMICONDUCTOR MEMORY TECHNOLOGY INC., HSINCHU (TW)

(21) Appl. No.: 13/226,269

(22) Filed: Sep. 6, 2011

(51) Int. Cl. H03L 7/00

(52) U.S. Cl. 327/141

(57) ABSTRACT

A delay circuit includes at least a delay stage. The delay stage includes an inverting receiver, a capacitive element, an output inverter, and a feedback transistor. The inverting receiver includes a resistive element. An input node of the inverting receiver receives an input signal, and the resistive element is coupled to an output node and an internal node of the inverting receiver. A capacitive element is coupled to the output node of the inverting receiver. An input node of the output inverter is coupled to the output node of the inverting receiver, and an output node of the output inverter outputs an output signal of the delay stage. The feedback transistor is coupled between the output node and the input node of output inverter, such that the feedback transistor compensates a delay time of the inverting receiver as at least one of a process, a supply-voltage, and a temperature varies.

### BACKGROUND

1. Technical Field

The present disclosure relates to a delay circuit and a delay stage thereof, in particular, to a delay circuit with a substantially constant delay time independent of the process, the supply-voltage, and the temperature (PVT) variations.

2. Description of Related Art

Integrated circuits are fabricated using reduced feature-size technologies, which have significant variations in device characteristics across the PVT corners. PVT variations can lead to reduced rise and/or fall times. Reduced rise and/or fall times tend to appear as unexpected delay time because the signals do not reach their intended level until later than expected. For extracting maximum benefit from a given process technology, among other things, the delay time across various paths of the circuit has to be controlled such that the delay time variation across PVT is minimal.

For example, in memory devices, RC timing tracking is important. RC timing may dominate delay time amount of delay circuits and accordingly small RC timing variations are better. In general, the supply-voltage may rage between 1.2 volts˜1.5 volts, the operation temperature may range between −40° C.˜100° C., and there are process variations in the memory devices. Accordingly, RC timing may have large variations due to the PVT variations.

FIG. 1 is a circuit diagram of a conventional delay circuit. The delay circuit may be used as an output circuit. The delay circuit includes several delay stages 101. Each delay stage 101 may include an inverting receiver INV1, a capacitor C1, and an output inverter INV2. The inverting receiver INV1 is formed by a PMOS transistor P1, a NMOS transistor N1, and a resistor R1, and the capacitor C1 is implemented by a gate capacitance of a NMOS transistor N2. The output inverter INV2 is formed by a PMOS transistor P2 and a NMOS transistor N3, and the resistor R1 may be formed of a polysilicon resistor.

Though the resistor R1 and the capacitor C1 may be adapted to compensate PVT variations of the input signal IN for generating an output signal OUT independent of PVT variations, the operating characteristics of transistors vary with PVT variations. For example, the transistor may operate slowly under high temperature and quickly under low temperature on the contrary, and the operation speed of the transistor varies as the process or the supply-voltage changes. In other words, the rise and/or fall time of the voltage at the internal node Q1, the threshold voltages and currents of the transistors vary due to the PVT variations, and thus the output signals O1 and O2 in the different PVT conditions are divergent.

To sum up, the PVT variations in the delay circuit may cause its delay time to drift from its specified value. Thus, there is a need for an improved output circuit that almost maintains a specified delay time despite the PVT variations.

### SUMMARY

An exemplary embodiment of the present disclosure provides a delay circuit comprising at least one of delay stages serially connected, and each delay stage comprises an inverting receiver, a capacitive element, an output inverter, and a feedback transistor. The inverting receiver comprises a resistive element. An input node of the inverting receiver is adapted to receive an input signal, and the resistive element is coupled to an output node of the inverting receiver and an internal node of the inverting receiver. The capacitive element is coupled to the output node of the inverting receiver. An input node of the output inverter is coupled to the output node of the inverting receiver, and an output node of the output inverter is adapted to output an output signal of the delay stage. A control terminal of the feedback transistor is coupled to the output node of the output inverter, a first terminal of the feedback transistor is coupled to the input node of output inverter, and a second terminal of the feedback transistor is coupled to a predetermined level, such that the feedback transistor is adapted to compensate a delay time of the inverting receiver as at least one of a process, a supply-voltage, and a temperature varies.

According to one exemplary embodiment of the present disclosure, the feedback transistor is a first NMOS transistor. A gate of the first transistor is the control terminal, a drain of the first transistor is the first terminal, a source of the first transistor is the second terminal, and the predetermined level is a ground.

According to one exemplary embodiment of the present disclosure, the feedback transistor is a first PMOS transistor. A gate of the first transistor is the control terminal, a drain of the first transistor is the first terminal, a source of the first transistor is the second terminal, and the predetermined level is the supply-voltage.

To sum up, the delay stage of the delay circuit according to the exemplary embodiment of the present disclosure has the feedback transistor may be adapted to compensate the delay time of the inverting receiver as at least one of a process, a supply-voltage, and a temperature varies. Therefore, the delay circuit formed by the serially connected delay stage is independent of the PVT variations.

In order to further understand the techniques, means and effects the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a circuit diagram of a conventional delay circuit.

FIG. 2 is a circuit diagram of a delay circuit according to an exemplary embodiment of the present disclosure.

FIG. 3 is a circuit diagram of a delay circuit according to another one exemplary embodiment of the present disclosure.

FIG. 4 is wave diagram showing the output signals of the 10^{th} delay stages in the delay circuit 2 of FIG. 2 and the delay circuit 1 of FIG. 1.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

In a delay stage of a delay circuit independent of the PVT variations according to exemplary embodiments of the present disclosure, a feedback transistor coupled between the input and output terminals of the output inverter is adapted to compensate the delay time of the inverting receiver as the temperature and the supply-voltage simultaneously vary. Furthermore, the feedback transistor may be adapted to compensate the delay time of the inverting receiver as the temperature, the supply-voltage, and the process simultaneously vary.

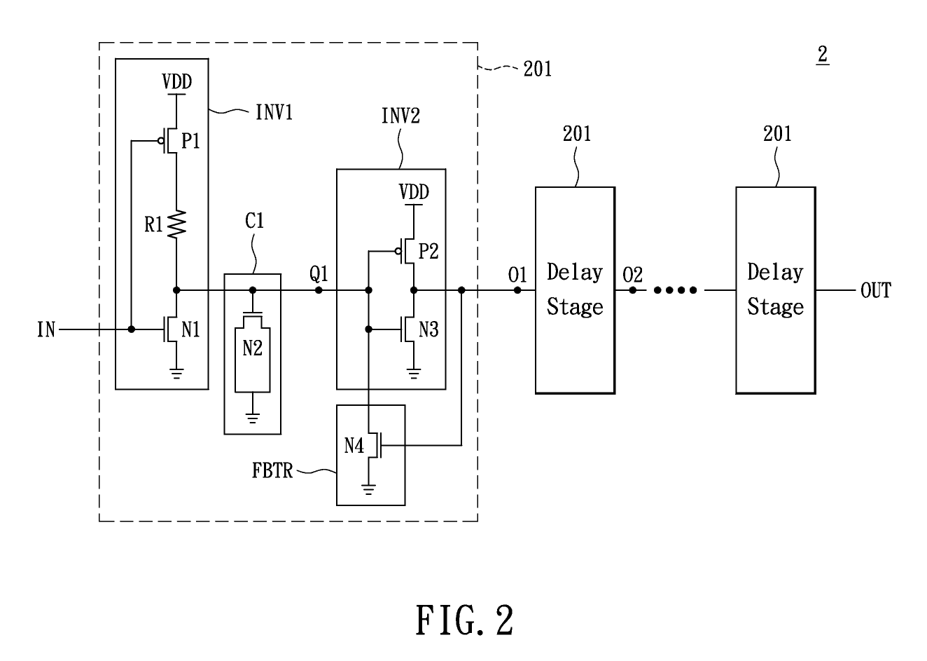

Referring to FIG. 2, FIG. 2 is a circuit diagram of a delay circuit according to an exemplary embodiment of the present disclosure. The delay circuit 2 comprises several delay stages 201, and each delay stage 201 comprises an inverting receiver INV1, a capacitor C1, an output inverter INV2, and a feedback transistor FBTR. Please note, in exemplary embodiments of the present disclosure, the inverting receiver INV1 is different from the well-known CMOS inverter merely having a PMOS transistor and an NMOS transistor.

The inverting receiver INV1 is formed by a PMOS transistor P1, a NMOS transistor N1, and a resistor R1, and the capacitor C1 is implemented by a gate capacitance of a NMOS transistor N2. The output inverter INV2 is formed by a PMOS transistor P2 and a NMOS transistor N3, and the resistor R1 may be formed of a polysilicon resistor. In the exemplary embodiment, the feedback transistor FBTR is implemented by a NMOS transistor N4.

In the inverting receiver INV1, gates of the PMOS transistor P1 and the NMOS transistor N1 are adapted to receive the input signal of the delay stage 201. For example, the input signal of the first delay stage 201 is the input signal IN, and the input signal of the second delay stage 201 is the output signal O1 of the first delay stage 201. The resistor R1 is coupled between drains of the PMOS transistor P1 and the NMOS transistor N1. Source of the PMOS transistor P1 and the NMOS transistor N1 are respectively coupled to a supply-voltage VDD and a ground. The drain of the NMOS transistor N1 is further coupled to an internal node Q1 of the delay stage 201.

In the capacitor C1, a source and a drain of the NMOS transistor N2 is coupled to the ground, and a gate of the NMOS transistor N2 is coupled to the internal node Q1. In the feedback transistor FBTR, a source of the NMOS transistor N4 is coupled to the ground, a gate of the NMOS transistor N4 is adapted to receive the output signal of the delay stage 201. For example, the first delay stage 201 outputs the output signal O1, the second delay stage 201 outputs the output signal O2, and the last delay stage 201 outputs the output signal OUT. A drain of the NMOS transistor N4 is coupled to the internal node Q1.

In the output inverter INV2, gates of the PMOS transistor P2 and the NMOS transistor N3 are coupled to the internal node Q1. Sources of the PMOS transistor P2 and the NMOS transistor N3 are respectively coupled to the supply-voltage VDD and the ground, and drains of the PMOS transistor P2 and the NMOS transistor N3 are adapted to outputs the output signal of the delay stage 201.

Taking the first delay stage 201 as an example, the inverting receiver INV1 receives the input signal IN of the delay stage 201 and outputs an inverted input signal at the internal node Q1. The resistor R1 and capacitor C1 are still adapted to compensate PVT variations of the input signal IN for generating an output signal OUT independent of PVT variations. The output inverter INV2 receives the inverted input signal at the internal node Q1, and thus outputs the delayed input signal as the output signal O1. The output signal O1 is feedback to the feedback transistor FBTR being adapted to compensate the delay time of the inverting receiver INV1 due to the PVT variations. Therefore, the output signals O1, O2, and OUT in the different PVT conditions may not be divergent, or the diversions of the signals O1, O2, and OUT in the different PVT conditions are reduced.

Taking the first delay stage 201 as an example, when the input signal IN changes from the high level to the low level, the delay effect occurs. The delay time is determined by the RC time constant of the resistor R1 and capacitor C1 ideally, and independent of the other devices. However, the conduction strength of the PMOS transistor P1 affects the delay time. The NMOS transistor N4 is used to compensate the delay time effect due to the PMOS transistor P1. To put it concretely, the response of the NMOS transistor N4 to the voltage and temperature variations is positive to the PMOS transistor P1. In other words, the weaker the conduction strength of the PMOS transistor P1 is, the weaker the conduction strength of the NMOS transistor N4 is. The stronger the conduction strength of the PMOS transistor P1 is, the stronger the conduction strength of the NMOS transistor N4 is. Therefore, the more stable signal at the internal node Q1 is provided, and the stable delay time of the delay stage 201 is obtained.

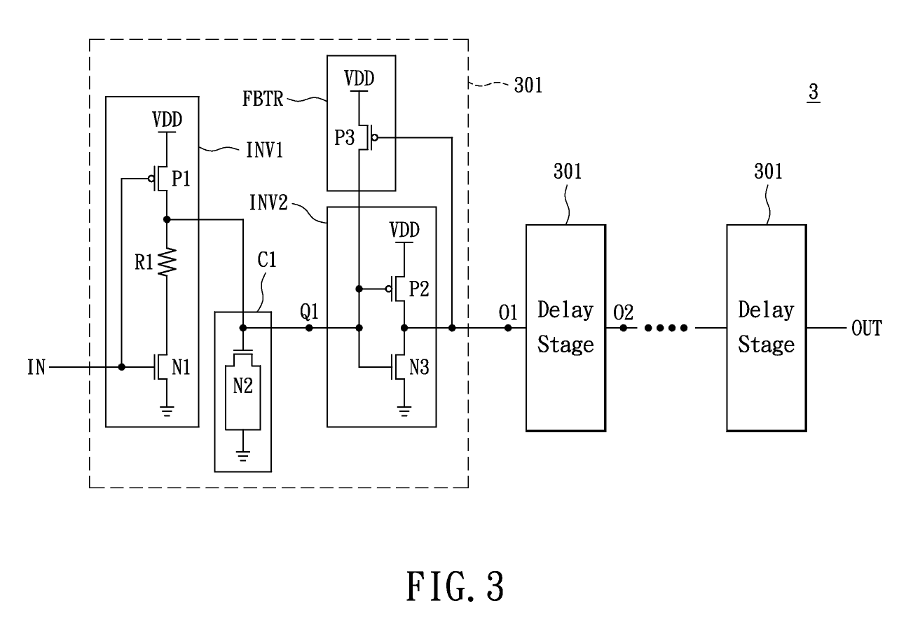

Referring to FIG. 3, FIG. 3 is a circuit diagram of a delay circuit according to another one exemplary embodiment of the present disclosure. Being different from the FIG. 2, the feedback transistor FBTR in FIG. 3 is implemented by a PMOS transistor P3, and the internal node Q1 in the delay stage 201 in FIG. 3 is coupled to the drain of the PMOS transistor. A source of the PMOS transistor P4 is coupled to the supply-voltage VDD, a gate of the PMOS transistor P4 is still adapted to receive the output signal of the delay stage 301, and a drain of the PMOS transistor P4 is still coupled to the internal node Q1.

Taking the first delay stage 301 as an example, when the input signal IN changes from the low level to the high level, the delay effect occurs. The delay time is determined by the RC time constant of the resistor R1 and capacitor C1 ideally, and independent of the other devices. However, the conduction strength of the NMOS transistor N1 affects the delay time. The PMOS transistor P3 is used to compensate the delay time effect due to the NMOS transistor N1. To put it concretely, the response of the PMOS transistor P3 to the voltage and temperature variations is positive to the NMOS transistor N1. In other words, the weaker the conduction strength of the NMOS transistor N1 is, the weaker the conduction strength of the PMOS transistor P3 is. The stronger the conduction strength of the NMOS transistor N1 is, the stronger the conduction strength of the PMOS transistor P3 is. Therefore, the more stable signal at the internal node Q1 is provided, and the stable delay time of the delay stage 301 is obtained.

It is noted that, although each of the above delay circuits includes the identical delay stage, the present disclosure is not limited thereto. In other words, the delay circuit may comprise the delay stages 201 and 301 connected serially. Furthermore, the feedback transistor is not limited to be the NMOS or PMOS transistor. The feedback transistor may be implemented by the NPN or the PNP transistor.

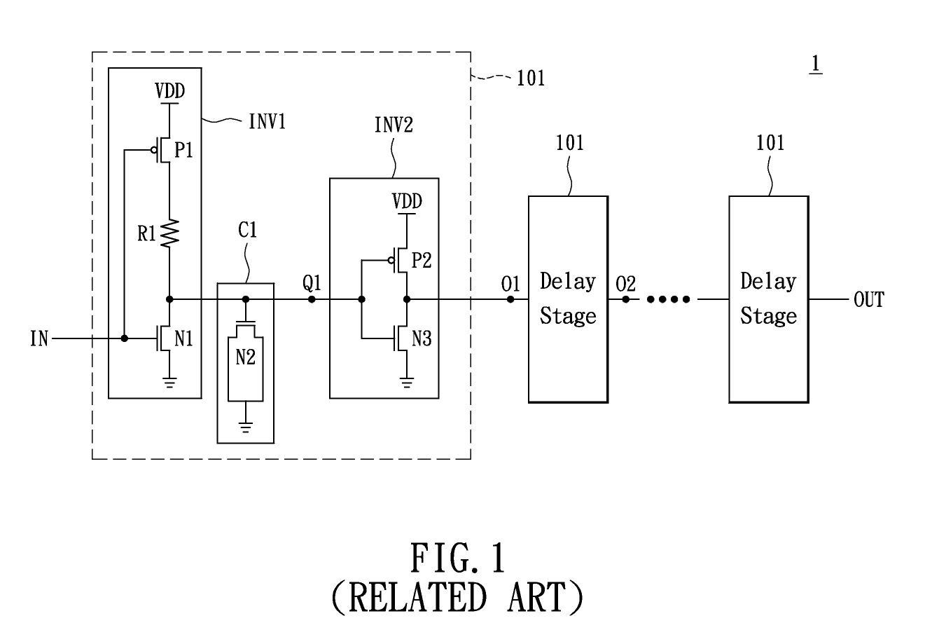

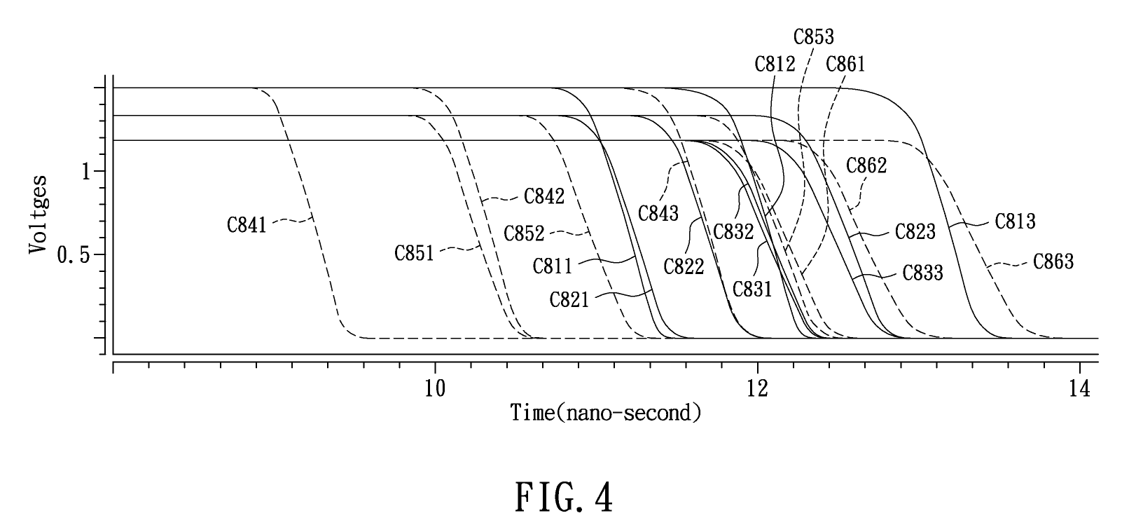

Referring to FIG. 4, FIG. 4 is wave diagram showing the output signals of the 10^{th} delay stages in the delay circuit 2 of FIG. 2 and the delay circuit 1 of FIG. 1. In FIG. 4, the curves C811, C812, and C813 are present of the output signals of the 10^{th} delay stage in the delay circuit 2 when the supply-voltage 1.5 volts and the temperatures are respectively −40° C., 25° C., and 100° C. The curves C821, C822, and C823 are present of the output signals of the 10^{th} delay stage in the delay circuit 2 when the supply-voltage 1.35 volts and the temperatures are respectively −40° C., 25° C., and 100° C. The curves C831, C832, and C833 are present of the output signals of the 10^{th} delay stage in the delay circuit 2 when the supply-voltage 1.2 volts and the temperatures are respectively −40° C., 25° C., and 100° C.

In FIG. 4, the curves C841, C842, and C843 are present of the output signals of the 10^{th} delay stage in the conventional delay circuit 1 when the supply-voltage 1.5 volts and the temperatures are respectively −40° C., 25° C., and 100° C. The curves C851, C852, and C853 are present of the output signals of the 10^{th} delay stage in the conventional delay circuit 1 when the supply-voltage 1.35 volts and the temperatures are respectively −40° C., 25° C., and 100° C. The curves C861, C862, and C863 are present of the output signals of the 10^{th} delay stage in the conventional delay circuit 1 when the supply-voltage 1.2 volts and the temperatures are respectively −40° C., 25° C., and 100° C.

The delay time of the output signal of the 10^{th} delay stage in the delay circuit 2 being represented by the curve C822 is taken as the comparison basis to the other output signals of the 10^{th} delay stage in the delay circuit 2 being represented by the curves C811˜C813, C821, C823, and C831˜C833. The maximum delay time difference ratio of the delay circuit 2 occurred due to the voltage and temperature variations is 17.7%. The delay time of the output signal of the 10^{th} delay stage in the delay circuit 1 being represented by the curve C852 is taken as the comparison basis to the other output signals of the 10^{th} delay stage in the delay circuit 2 being represented by the curves C841˜C843, C851, C853, and C861˜C863. The maximum delay time difference ratio of the conventional delay circuit 1 occurred due to the voltage and temperature variations is 39.9%.

From the above results of FIG. 4, the maximum delay time difference ratio in the delay circuit 2 occurred due to the voltage and temperature variations is less than that the maximum delay time difference ratio in the conventional delay circuit 1 occurred due to the voltage and temperature variations. Moreover, when the process, voltage and temperature variations are considered, the maximum delay time difference ratio in the delay circuit 2 is 35%, which is less than the maximum delay time difference ratio in the conventional delay circuit 1.

In summary, the delay stage of the delay circuit according to the exemplary embodiment of the present disclosure has the feedback transistor may be adapted to compensate the delay time of the inverting receiver as the supply-voltage and the temperature simultaneously vary. Moreover, the feedback transistor also can compensate the delay time of the inverting receiver as the process, the supply-voltage, and the temperature simultaneously vary.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A delay circuit comprising at least one of delay stages serially connected, and the delay stage comprises:
an inverting receiver, comprising a resistive element, an input node of the inverting receiver is adapted to receive an input signal, and the resistive element is coupled to an output node of the inverting receiver and an internal node of the inverting receiver;
a capacitive element, coupled to the output node of the inverting receiver;
an output inverter, an input node of the output inverter is coupled to the output node of the inverting receiver, and an output node of the output inverter is adapted to output an output signal of the delay stage; and
a feedback transistor, a control terminal of the feedback transistor is coupled to the output node of the output inverter, a first terminal of the feedback transistor is coupled to the input node of output inverter, and a second terminal of the feedback transistor is coupled to a predetermined level, such that the feedback transistor is adapted to compensate a delay time of the inverting receiver as at least one of a process, a supply-voltage, and a temperature varies.

2. The delay circuit according to claim 1, wherein the feedback transistor is a first NMOS transistor, a gate of the first NMOS transistor is the control terminal, a drain of the first NMOS transistor is the first terminal, a source of the first NMOS transistor is the second terminal, and the predetermined level is a ground.

3. The delay circuit according to claim 1, wherein the feedback transistor is a first PMOS transistor, a gate of the first PMOS transistor is the control terminal, a drain of the first PMOS transistor is the first terminal, a source of the first PMOS transistor is the second terminal, and the predetermined level is the supply-voltage.

4. The delay circuit according to claim 2, wherein the inverting receiver further comprises:
a second NMOS transistor, a gate of the second NMOS transistor is coupled to the input node of the inverting receiver, a source of the second NMOS transistor is coupled to a ground, and a drain of the second NMOS transistor is coupled to the resistive element; and
a second PMOS transistor, a gate of the second PMOS transistor is coupled to the input node of the inverting receiver, a source of the second PMOS transistor is coupled to the supply-voltage, and a drain of the second PMOS transistor is coupled to the resistive element;
wherein a first terminal of the resistive element is coupled to the internal node of the inverting receiver, a second terminal of the resistive element is coupled to the output node of the inverting receiver, and the drain of the second NMOS transistor is coupled to the output node of the output node of the inverting receiver.

5. The delay circuit according to claim 3, wherein the inverting receiver further comprises:
a second NMOS transistor, a gate of the second NMOS transistor is coupled to the input node of the inverting receiver, a source of the second NMOS transistor is coupled to a ground, and a drain of the second NMOS transistor is coupled to the resistive element; and
a second PMOS transistor, a gate of the second PMOS transistor is coupled to the input node of the inverting receiver, a source of the second PMOS transistor is coupled to the supply-voltage, and a drain of the second PMOS transistor is coupled to the resistive element;
wherein a first terminal of the resistive element is coupled to the internal node of the inverting receiver, a second terminal of the resistive element is coupled to the output node of the inverting receiver, and the drain of the second PMOS transistor is coupled to the output node of the output node of the inverting receiver.

6. The delay circuit according to claim 1, wherein the output inverter comprises:
a third NMOS transistor, a gate of the third NMOS transistor is coupled to the input node of the output inverter, a source of the third NMOS transistor is coupled to a ground, and a drain of the third NMOS transistor is coupled to the output node of the output inverter; and
a third PMOS transistor, a gate of the third PMOS transistor is coupled to the input node of the output inverter, a source of the third PMOS transistor is coupled to supply-voltage, and a drain of the third PMOS transistor is coupled to the output node of the output inverter.

7. The delay circuit according to claim 1, wherein the capacitive element comprises a fourth NMOS transistor, a gate of the fourth NMOS transistor is coupled to the output node of the inverting receiver and the input node of the output inverter, a source and a drain of the fourth NMOS transistor are coupled to a ground.

8. A delay stage included in a delay circuit, comprising:
an inverting receiver, comprising a resistive element, an input node of the inverting receiver is adapted to receive an input signal, and the resistive element is coupled to an output node of the inverting receiver and an internal node of the inverting receiver;
a capacitive element, coupled to the output node of the inverting receiver;
an output inverter, an input node of the output inverter is coupled to the output node of the inverting receiver, and an output node of the output inverter is adapted to output an output signal of the delay stage; and
a feedback transistor, a control terminal of the feedback transistor is coupled to the output node of the output inverter, a first terminal of the feedback transistor is coupled to the input node of output inverter, and a second terminal of the feedback transistor is coupled to a predetermined level, such that the feedback transistor is adapted to compensate a delay time of the inverting receiver as at least one of a process, a supply-voltage, and a temperature varies.

9. The delay stage according to claim 8, wherein the feedback transistor is a first NMOS transistor, a gate of the first NMOS transistor is the control terminal, a drain of the first NMOS transistor is the first terminal, a source of the first NMOS transistor is the second terminal, and the predetermined level is a ground.

10. The delay stage according to claim 8, wherein the feedback transistor is a first PMOS transistor, a gate of the first PMOS transistor is the control terminal, a drain of the first PMOS transistor is the first terminal, a source of the first PMOS transistor is the second terminal, and the predetermined level is the supply-voltage.

11. The delay stage according to claim 9, wherein the inverting receiver further comprises:
a second NMOS transistor, a gate of the second NMOS transistor is coupled to the input node of the inverting receiver, a source of the second NMOS transistor is coupled to a ground, and a drain of the second NMOS transistor is coupled to the resistive element; and
a second PMOS transistor, a gate of the second PMOS transistor is coupled to the input node of the inverting receiver, a source of the second PMOS transistor is coupled to the supply-voltage, and a drain of the second PMOS transistor is coupled to the resistive element;
wherein a first terminal of the resistive element is coupled to the internal node of the inverting receiver, a second terminal of the resistive element is coupled to the output node of the inverting receiver, and the drain of the second NMOS transistor is coupled to the output node of the output node of the inverting receiver.

12. The delay stage according to claim 10, wherein the inverting receiver further comprises:
a second NMOS transistor, a gate of the second NMOS transistor is coupled to the input node of the inverting receiver, a source of the second NMOS transistor is coupled to a ground, and a drain of the second NMOS transistor is coupled to the resistive element; and
a second PMOS transistor, a gate of the second PMOS transistor is coupled to the input node of the inverting receiver, a source of the second PMOS transistor is coupled to the supply-voltage, and a drain of the second PMOS transistor is coupled to the resistive element;
wherein a first terminal of the resistive element is coupled to the internal node of the inverting receiver, a second terminal of the resistive element is coupled to the output node of the inverting receiver, and the drain of the second PMOS transistor is coupled to the output node of the output node of the inverting receiver.

13. The delay stage according to claim 8, wherein the output inverter comprises:
a third NMOS transistor, a gate of the third NMOS transistor is coupled to the input node of the output inverter, a source of the third NMOS transistor is coupled to a ground, and a drain of the third NMOS transistor is coupled to the output node of the output inverter; and
a third PMOS transistor, a gate of the third PMOS transistor is coupled to the input node of the output inverter, a source of the third PMOS transistor is coupled to supply-voltage, and a drain of the third PMOS transistor is coupled to the output node of the output inverter.

14. The delay stage according to claim 8, wherein the capacitive element comprises a fourth NMOS transistor, a gate of the fourth NMOS transistor is coupled to the output node of the inverting receiver and the input node of the output inverter, a source and a drain of the fourth NMOS transistor are coupled to a ground.
